(19) United States
(12) Patent Application Publication
(10) Pub. No.: US 2026/0282591 A1
(43) Pub. Date: Sep. 17, 2026

(54) PHOTODETECTOR AND PHOTODETECTION SYSTEM

(71) Applicant: Kabushiki Kaisha Toshiba, Kawasaki-shi (JP)

(72) Inventors: Rei Hashimoto, Edogawa Tokyo (JP); Shinji Saito, Yokohama Kanagawa (JP); Tsutomu Kakuno, Fujisawa Kanagawa (JP); Kei Kaneko, Yokohama Kanagawa (JP); Masatoshi Hirono, Yokohama Kanagawa (JP); Tetsuya Miyagawa, Yokohama Kanagawa (JP)

(21) Appl. No.: 19/561,235

(22) Filed: Mar. 9, 2026

(30) Foreign Application Priority Data
Mar. 17, 2025 (JP) 2025-042413

(51) Int. Cl. H10F 55/255; G01J 1/44; H10F 77/124; H10F 77/14

(52) U.S. Cl. CPC H10F 55/255; G01J 1/44; H10F 77/1248; H10F 77/146

(57) ABSTRACT

According to one embodiment, a photodetector includes a first detector and a second detector. Each of the first detector and the second detector includes a stacked member including a detection layer. The detection layer includes a plurality of first semiconductor films, and a second semiconductor film provided between the plurality of first semiconductor films. A first number of the plurality of first semiconductor films included in the detection layer of the first detector is smaller than a second number of the plurality of first semiconductor films included in the detection layer of the second detector.

### CROSS-REFERENCE TO RELATED APPLICATIONS

This application is based upon and claims the benefit of priority from Japanese Patent Application No. 2025-042413, filed on Mar. 17, 2025; the entire contents of which are incorporated herein by reference.

### FIELD

Embodiments described herein relate generally to a photodetector and a photodetection system.

### BACKGROUND

For example, there is a photodetector including a photoelectric conversion layer. It is desirable for the photodetector to be able to detect detection target light with high sensitivity.

### BRIEF DESCRIPTION OF THE DRAWINGS

FIG. 1 is a schematic cross-sectional view illustrating a photodetector according to a first embodiment;

FIG. 2 is a schematic cross-sectional view illustrating a photodetector according to a second embodiment;

FIG. 3 is a schematic cross-sectional view illustrating a photodetection system according to a third embodiment; and

FIG. 4 is a schematic cross-sectional view illustrating a photodetector according to the fourth embodiment.

### DETAILED DESCRIPTION

According to one embodiment, a photodetector includes a first detector and a second detector. Each of the first detector and the second detector includes a stacked member including a detection layer. The detection layer includes a plurality of first semiconductor films, and a second semiconductor film provided between the plurality of first semiconductor films. A first number of the plurality of first semiconductor films included in the detection layer of the first detector is smaller than a second number of the plurality of first semiconductor films included in the detection layer of the second detector.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

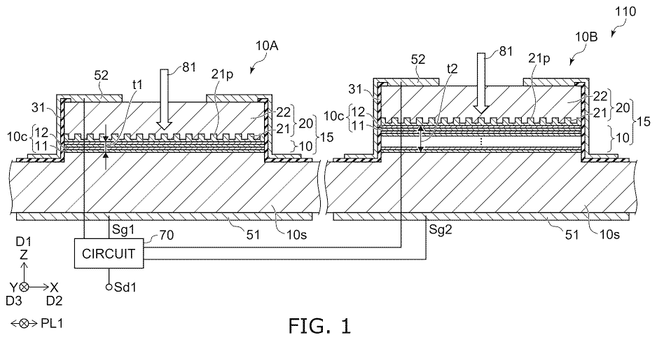

FIG. 1 is a schematic cross-sectional view illustrating a photodetector according to a first embodiment.

As shown in FIG. 1, a photodetector 110 according to the embodiment includes a first detector 10A and a second detector 10B.

Each of the first detector 10A and the second detector 10B includes a stacked member 15 including a detection layer 10. The detection layer 10 includes a plurality of first semiconductor films 11 and a second semiconductor film 12 provided between the plurality of first semiconductor films 11.

A number (first number) of the plurality of first semiconductor films 11 included in the detection layer 10 of the first detector 10A is smaller than a number (second number) of the plurality of first semiconductor films 11 included in the detection layer 10 of the second detector 10B.

The first number may be 2 or more. In a case where the first number is 2, the number of the second semiconductor films 12 is 1. In a case where the second number is 3 or more, the number of the second semiconductor films 12 may be 2. The first semiconductor films 11 and the second semiconductor films 12 may be provided alternately. The first number may be, for example, 10 or less.

The second number may be, for example, more than 10 and not more than 100. In the second detector 10B, one of the plurality of first semiconductor films 11 is between one of the plurality of second semiconductor films 12 and another one of the plurality of second semiconductor films 12. One of the plurality of second semiconductor films 12 is between one of the plurality of first semiconductor films 11 and another one of the plurality of first semiconductor films 11. The first semiconductor films 11 and the second semiconductor films 12 may be provided alternately.

The detection layer 10 corresponds to a photoelectric conversion layer. When detection target light 81 is incident on the detection layer 10, mobile carriers are generated. The detection target light 81 can be detected by detecting the carriers.

In general, in a case where the intensity of the detection target light 81 is high, it has been thought that if the number of semiconductor films provided in the detection layer 10 is large, the amount of carriers generated is large and high sensitivity is obtained. However, in a case where the intensity of the detection target light 81 is low, a phenomenon in which sensitivity decreases when the number of semiconductor films is large may occur. This is thought to be due to the phenomena that when the intensity of the detection target light is low, the detection target light is absorbed by some of the semiconductor films, and the detection target light 81 does not reach the remaining part of the semiconductor films.

In the embodiment, as described above, plurality of detection sections are provided. The number of plurality of first semiconductor films 11 differs in the plurality of detection sections. For example, in the first detector 10A in which the number of plurality of first semiconductor films 11 is small, the detection target light 81 of a relatively low intensity can be detected with high sensitivity. On the other hand, in the second detector 10B in which the number of plurality of first semiconductor films 11 is large, the detection target light 81 of a relatively high intensity can be detected with high sensitivity. According to the embodiment, the detection target light 81 of a wide intensity range can be detected with high sensitivity. According to the embodiment, a photodetector that can obtain high sensitivity can be provided.

The photodetector 110 according to the embodiment can be applied to, for example, detection of a target substance. For example, the target substance may include, for example, a gas. The gas may include, for example, at least one of carbon dioxide, methane, and N₂O. According to the embodiment, the target substance can be detected with high sensitivity.

The detection layer 10 is along a first plane PL1. A first direction D1 that crosses the first plane PL1 is defined as a Z-axis direction. A direction perpendicular to the Z-axis direction is defined as an X-axis direction. A direction perpendicular to the Z-axis direction and the X-axis direction is defined as a Y-axis direction. The first plane PL1 is along, for example, the X-Y plane. A second direction D2 that crosses the first direction D1 is along, for example, the X-axis direction. A third direction D3 crosses a plane including the first direction D1 and the second direction D2. The third direction D3 may be, for example, the Y-axis direction.

As shown in FIG. 1, the stacked member 15 may further include a photonic crystal layer 20. The photonic crystal layer 20 is configured to supply the detection layer with the detection target light 81 being incident on the photonic crystal layer 20. In the photonic crystal layer 20, the traveling direction of the light changes.

A direction from the detection layer 10 to the photonic crystal layer 20 is along the first direction D1. The photonic crystal layer 20 includes, for example, a first crystal layer 21 and a second crystal layer 22. The first crystal layer 21 includes a plurality of first crystal regions 21p arranged along the first plane PL1. A part of the second crystal layer 22 is between the plurality of first crystal regions 21p. The refractive index of the first crystal layer 21 is different from the refractive index of the second crystal layer 22. Due to the difference in the refractive index, the traveling direction of the detection target light 81 that is incident on the photonic crystal layer 20 changes, and the detection target light 81 spreads along the photonic crystal layer 20. The detection target light 81 being spread is incident on the detection layer 10.

By using the photonic crystal layer 20, for example, the restriction on the angle of incidence of the detection target light 81 is alleviated. The range of appropriate angles of incidence at which high sensitivity can be obtained is expanded. The detection target light 81 over a relatively wide range of angles of incidence can be detected with high sensitivity.

In a case where the photonic crystal layer 20 is provided to alleviate the restriction on the angle of incidence, the light incident on the detection layer 10 is attenuated. When the detection layer 10 is combined with the photonic crystal layer 20, the above-mentioned problems that arise when the light intensity is low tend to become more apparent. For this reason, when the detection layer 10 is combined with the photonic crystal layer 20, the effect of changing the number of plurality of semiconductor layers in plurality of detection sections is more pronounced.

As shown in FIG. 1, a thickness of the detection layer 10 included in the first detector 10A along the first direction D1 is defined as a first thickness t1. A thickness of the detection layer 10 included in the second detector 10B along the first direction D1 is defined as a second thickness t2. The first thickness t1 may be thinner than the second thickness t2. The first thickness t1 is, for example, not less than 50 nm and less than 500 nm. The second thickness t2 is, for example, not less than 500 nm and not more than 5000 nm.

As shown in FIG. 1, each of the first detector 10A and the second detector 10B may further include a first electrode 51 and a second electrode 52. At least a part of the stacked member 15 is provided between the first electrode 51 and the second electrode 52.

An electrical signal generated between the first electrode 51 and the second electrode 52 is configured to change according to the detection target light 81 that is incident on the photonic crystal layer 20.

In detecting the detection target light 81, a bias voltage may be applied between the first electrode 51 and the second electrode 52.

As shown in FIG. 1, the photodetector 110 may further include a controller 70. The controller 70 may be electrically connected to the first electrode 51 and the second electrode 52 included in the first detector 10A, and the first electrode 51 and the second electrode 52 included in the second detector 10B.

The controller 70 is configured to output a detection signal Sd1 according to the detection target light 81. In a first state, the detection signal Sd1 is based on a first signal Sg1 obtained from the first detector 10A. In a second state, the detection signal Sd1 is based on a second signal Sg2 obtained from the second detector 10B. A first intensity of the detection target light 81 in the first state is lower than a second intensity of the detection target light 81 in the second state.

In this way, the controller 70 may switch between the first signal Sg1 and the second signal Sg2 according to the intensity of the detection target light 81, and output it as the detection signal Sd1.

In the embodiment, the detection layer 10 may include a quantum cascade active layer 10c. A subband transition of carriers occurs in the detection layer 10.

The quantum cascade active layer 10c includes the plurality of first semiconductor films 11 and the second semiconductor films 12 described above.

The plurality of first semiconductor films 11 included in the first detector 10A include, for example, In_{z1}Ga_{1-z1}As (0<z1<1). The second semiconductor film 12 included in the first detector 10A includes, for example, In_{z2}Al_{1-z2}As (0<z2<1).

The plurality of first semiconductor films 11 included in the second detector 10B include, for example, In_{z3}Ga_{1-z3}As (0<z3<1). The second semiconductor film 12 included in the second detector 10B includes, for example, In_{z4}Al_{1-z4}As (0<z4<1).

The composition ratios z1, z2, z3 and z4 may satisfy one of the following a first condition, a second condition, a third condition, and a fourth condition.

In the first condition, the composition ratio z1 is the same as the composition ratio z3, and the composition ratio z2 is the same as the composition ratio z4. In the second condition, the composition ratio z1 is the same as the composition ratio z3, and the composition ratio z2 is different from the composition ratio z4. In the third condition, the composition ratio z1 is different from the composition ratio z3, and the composition ratio z2 is the same as the composition ratio z4. In the fourth condition, the composition ratio z1 is different from the composition ratio z3, and the composition ratio z2 is different from the composition ratio z4.

Each of the first detector 10A and the second detector 10B may further include a base 10s. At least a part of the base 10s is between the first electrode 51 and the second electrode 52. At least a part of the detection layer 10 is between the base 10s and the second electrode 52. At least a part of the photonic crystal layer 20 is between the detection layer 10 and the second electrode 52.

The base 10s included in the first detector 10A may be continuous with the base 10s included in the second detector 10B. The base 10s included in the first detector 10A may be discontinuous with the base 10s included in the second detector 10B.

As shown in FIG. 1, each of the first detector 10A and the second detector 10B may further include an insulating member 31. The insulating member 31 faces the side face of the stacked member 15.

### Second Embodiment

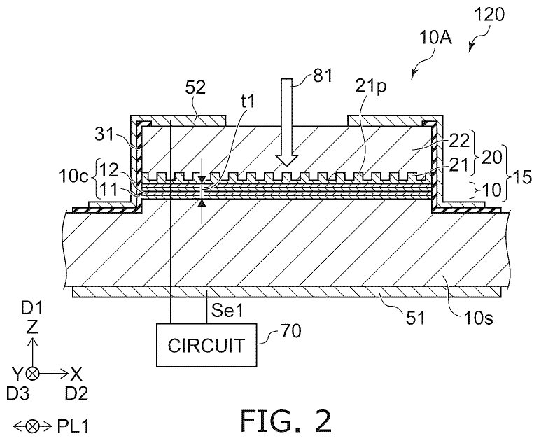

FIG. 2 is a schematic cross-sectional view illustrating a photodetector according to a second embodiment.

As shown in FIG. 2, a photodetector 120 according to the embodiment includes the first electrode 51, the second electrode 52, and the stacked member 15. At least a part of the stacked member 15 is between the first electrode 51 and the second electrode 52.

The stacked member 15 includes the detection layer 10 and the photonic crystal layer 20. The detection layer 10 includes the plurality of first semiconductor films 11 and the second semiconductor film 12 provided between the plurality of first semiconductor films 11.

The photonic crystal layer 20 is configured to supply the detection layer 10 with the detection target light 81 that is incident on the photonic crystal layer 20.

The electrical signal Se1 generated between the first electrode 51 and the second electrode 52 is configured to change according to the detection target light 81 that is incident on the photonic crystal layer 20.

The number of the first semiconductor films 11 (first number) is 2 or more and 10 or less. This allows the detection target light 81 with a relatively low intensity with high sensitivity. As already explained, in a case where the detection layer 10 is combined with the photonic crystal layer 20, the above-mentioned problems that arise when the light intensity is low tend to become more apparent. In the photodetector 120, the limit on the angle of incidence is relaxed, and the detection target light 81 with a relatively low intensity with high sensitivity can be detected. According to the embodiment, a photodetector that can obtain high sensitivity can be provided.

In the photodetector 120, the configuration described for the first detector 10A of the photodetector 110 may be applied.

For example, the plurality of first semiconductor films 11 include In_{z1}Ga_{1-z1}As (0<z1<1). The second semiconductor film 12 includes In_{z2}Al_{1-z2}As (0<z2<1). For example, the detection layer 10 may include a quantum cascade active layer 10c. In the detection layer 10, a subband transition of carriers occurs.

### Third Embodiment

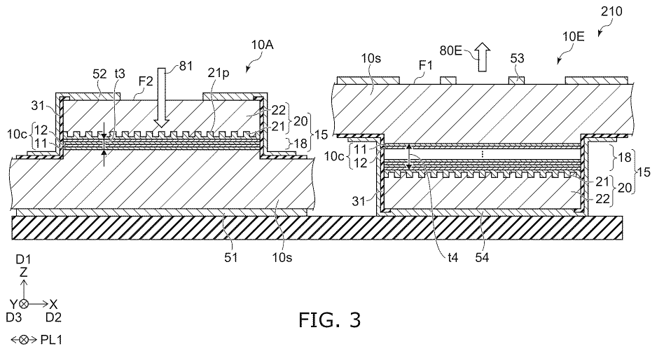

FIG. 3 is a schematic cross-sectional view illustrating a photodetection system according to a third embodiment.

As shown in FIG. 3, an photodetection system 210 according to the embodiment includes a first light-emitter 10E and a first detector 10A. The first light-emitter 10E is configured to emit the first light 80E. The first detector 10A is configured to detect detection target light 81 based on the first light 80E.

For example, each of the first light-emitter 10E and the first detector 10A includes the stacked member 15 including the stacked body 18.

The stacked body 18 includes the plurality of first semiconductor films 11 and the second semiconductor film 12 provided between the plurality of first semiconductor films 11. The number (first number) of the plurality of first semiconductor films 11 included in the stacked body 18 of the first detector 10A is smaller than the number (second number) of the plurality of first semiconductor films 11 included in the stacked body 18 of the first light-emitter 10E.

The first number may be 2 or more. When the first number is 2, the number of second semiconductor films 12 is 1. When the second number is 3 or more, the number of second semiconductor films 12 may be 2. The first semiconductor films 11 and the second semiconductor films 12 may be provided alternately. The first number may be, for example, 10 or less.

The second number may be, for example, more than 10 and not more than 100. In the first light-emitter 10E, one of the plurality of first semiconductor films 11 is between one of the plurality of second semiconductor films 12 and another one of the plurality of second semiconductor films 12. One of the plurality of second semiconductor films 12 is between one of the plurality of first semiconductor films 11 and another one of the plurality of first semiconductor films 11. The first semiconductor films 11 and the second semiconductor films 12 may be provided alternately.

In the first light-emitter 10E, the stacked body 18 corresponds to the light-emitting layer. The first light 80E emitted from the light-emitting layer is emitted from a first face F1 of the first light-emitter 10E. The first light 80E passes through a space including the target substance, after reflection, etc., and enters the first detector 10A as the detection target light 81. The detection target light 81 is incident on the stacked body 18 included in the first detector 10A, and mobile carriers are generated. By detecting the carriers, it is possible to detect the detection target light 81. The stacked body 18 included in the first detector 10A corresponds to a detection layer.

The first light 80E with a high intensity is obtained by the second number of the plurality of first semiconductor films 11 included in the first light-emitter 10E being large. The first light 80E passes through a space including the target substance. By passing through the target substance, the intensity of the first light 80E decreases. The low-intensity light is incident on the first detector 10A as the detection target light 81.

The detection target light 81 is incident on the second face F2 of the first detector 10A. The number of the plurality of first semiconductor films 11 included in the first detector 10A is small. This allows the detection target light 81 with a relatively low intensity to be detected with high sensitivity. According to the embodiment, a photodetection system with high sensitivity can be provided.

In the embodiment, the stacked body 18 included in the first light-emitter 10E may include a quantum cascade active layer 10c. A subband transition of carriers occurs in the stacked body 18 included in the first light-emitter 10E.

In the embodiment, the stacked body 18 included in the first detector 10A may include a quantum cascade active layer 10c. A subband transition of carriers occurs in the stacked body 18 included in the first detector 10A.

The quantum cascade active layer 10c includes the above-mentioned plurality of first semiconductor films 11 and second semiconductor film 12.

The first semiconductor films 11 included in the first detector 10A include, for example, In_{z1}Ga_{1-z1}As (0<z1<1). The second semiconductor film 12 included in the first detector 10A includes, for example, In_{z2}Al_{1-z2}As (0<z2<1).

The first semiconductor films 11 included in the first light-emitter 10E include, for example, In_{z3}Ga_{1-z3}As (0<z3<1). The second semiconductor film 12 included in the first light-emitter 10E includes In_{z4}Al_{1-z4}As (0<z4<1).

The composition ratios z1, z2, z3, and z4 may satisfy one of the following first condition, second condition, third condition, and fourth condition.

In the first condition, the composition ratio z1 is the same as the composition ratio z3, and the composition ratio z2 is the same as the composition ratio z4. In the second condition, the composition ratio z1 is the same as the composition ratio z3, and the composition ratio z2 is different from the composition ratio z4. In the third condition, the composition ratio z1 is different from the composition ratio z3, and the composition ratio z2 is the same as the composition ratio z4. In the fourth condition, the composition ratio z1 is different from the composition ratio z3, and the composition ratio z2 is different from the composition ratio z4.

In the photodetection system 210, the first number may be, for example, 2 or more and 10 or less. The second number may be more than 10 and 100 or less.

The stacked member 15 may further include a photonic crystal layer 20. The photonic crystal layer 20 included in the first light-emitter 10E overlaps the stacked body 18 included in the first light-emitter 10E. The photonic crystal layer 20 included in the first detector 10A overlaps the stacked body 18 included in the first detector 10A.

In this example, in the first light-emitter 10E, the stacked body 18 is between the photonic crystal layer 20 and the first face F1. In the first detector 10A, the photonic crystal layer 20 is between the stacked body 18 and the second face F2.

The photonic crystal layer 20 includes, for example, the first crystal layer 21 and the second crystal layer 22. The first crystal layer 21 includes the plurality of first crystal regions 21p arranged along the first plane PL1. A part of the second crystal layer 22 is between the plurality of first crystal regions 21p. The refractive index of the first crystal layer 21 is different from the refractive index of the second crystal layer 22. The difference in refractive index changes the traveling direction of the detection target light 81 that is incident on the photonic crystal layer 20.

In the first light-emitter 10E, the photonic crystal layer 20 is provided to obtain a surface-emitting light-emitter.

In the first detector 10A, the detection target light 81 being incident spreads along the photonic crystal layer 20. The detection target light 81 being spread is incident on the detection layer 10. The detection target light 81 can be detected with high sensitivity over a relatively wide range of angles of incidence.

As shown in FIG. 3, a thickness of the stacked body 18 included in the first detector 10A along the first direction D1 is defined as a third thickness t3. A thickness of the stacked body 18 included in the first light-emitter 10E along the first direction D1 is defined as a fourth thickness t4. The third thickness t3 may be thinner than the fourth thickness t4. The third thickness t3 is, for example, not less than 50 nm and less than 500 nm. The fourth thickness t4 is, for example, not less than 500 nm and not more than 5000 nm.

The first detector 10A may further include the first electrode 51 and the second electrode 52. At least a part of the stacked member 15 included in the first detector 10A is provided between the first electrode 51 and the second electrode 52.

The first light-emitter 10E may further include the third electrode 53 and the fourth electrode 54. At least a part of the stacked member 15 included in the first light-emitter 10E is provided between the third electrode 53 and the fourth electrode 54. The third electrode 53 may include, for example, a thin wire electrode.

The electrical signal generated between the first electrode 51 and the second electrode 52 is configured to change according to the detection target light 81 incident on the photonic crystal layer 20 of the first detector 10A.

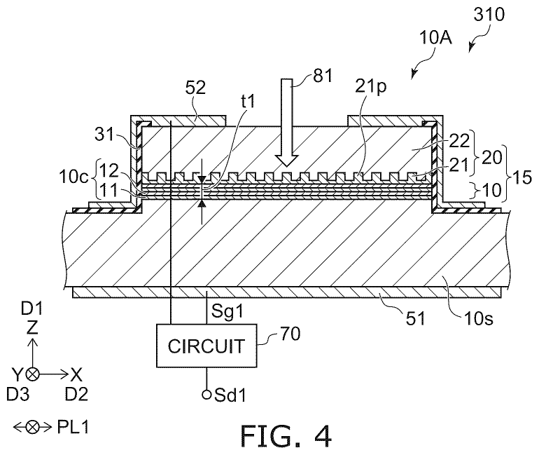

FIG. 4 is a schematic cross-sectional view illustrating a photodetector according to the fourth embodiment.

As shown in FIG. 4, a photodetector 310 according to the embodiment includes the first detection unit 10A. The configuration described in relation to the first embodiment may be applied to the first detector 10A in the fourth embodiment.

In the fourth embodiment, the first detector 10A includes stacked member 15 including a detection layer 10. The detection layer 10 includes the plurality of first semiconductor films 11 and the second semiconductor film 12 provided between the plurality of first semiconductor films 11. The stacked member 15 further includes the photonic crystal layer 20. The photonic crystal layer 20 is configured to supply the detection layer 10 with the detection target light 81 that is incident on the photonic crystal layer 20. The first detector 10A further includes the first electrode 51 and the second electrode 52. At least a part of the stacked member 15 is provided between the first electrode 51 and the second electrode 52. The electrical signal generated between the first electrode 51 and the second electrode 52 is configured to change in response to the detection target light 81 that is incident on the photonic crystal layer 20. The detection layer 20 includes a quantum cascade active layer 10c. The fourth embodiment also provides a photodetector that achieves high sensitivity.

The embodiment may include the following Technical proposals:

### Technical Proposal 1

A photodetector, comprising:
a first detector; and
a second detector,
each of the first detector and the second detector including a stacked member including a detection layer;
the detection layer including:
   a plurality of first semiconductor films, and
   a second semiconductor film provided between the plurality of first semiconductor films;
a first number of the plurality of first semiconductor films included in the detection layer of the first detector being smaller than a second number of the plurality of first semiconductor films included in the detection layer of the second detector.

### Technical Proposal 2

The photodetector according to Technical proposal 1, wherein
the plurality of first semiconductor films included in the first detector include In_{z1}Ga_{1-z1}As (0<z1<1), and
the second semiconductor film included in the first detector includes In_{z2}Al_{1-z2}As (0<z2<1).

### Technical Proposal 3

The photodetector according to Technical proposal 2, wherein
the plurality of first semiconductor films included in the second detector include In_{z3}Ga_{1-z3}As (0<z3<1), and
the second semiconductor film included in the second detector includes In_{z4}Al_{1-z4}As (0<z4<1).

### Technical Proposal 4

The photodetector according to Technical proposal 3, wherein
the z1, the z2, the z3, and z4 satisfy one of a first condition, the second condition, the third condition, and the fourth condition,
in the first condition, the z1 is the same as the z3, and the z2 is the same as the z4,
in the second condition, the z1 is the same as the z3, and the z2 is different from the z4,
in the third condition, the z1 is different from the z3, and the z2 is the same as the z4, and
in the fourth condition, the z1 is different from the z3, and the z2 is different from the z4.

### Technical Proposal 5

The photodetector according to any one of Technical proposals 1-4, wherein
the first number is not less than 2 and not more than 10, and
the second number is more than 10 and not more than 100.

### Technical Proposal 6

The photodetector according to any one of Technical proposals 1-5, wherein
the stacked member further includes a photonic crystal layer, and
the photonic crystal layer is configured to supply the detection layer with a detection target light being incident on the photonic crystal layer.

### Technical Proposal 7

The photodetector according to Technical proposal 6, wherein
the first detector and the second detector each further include a first electrode and a second electrode, and
at least a part of the stacked member is provided between the first electrode and the second electrode.

### Technical Proposal 8

The photodetector according to Technical proposal 7, wherein
an electrical signal generated between the first electrode and the second electrode is configured to change according to the detection target light that is incident on the photonic crystal layer.

### Technical Proposal 9

The photodetector according to any one of Technical proposals 6-8, further comprising:
a controller,
the controller being configured to output a detection signal corresponding to the detection target light,
in a first state, the detection signal is based on a first signal obtained from the first detector,
in a second state, the detection signal is based on a second signal obtained from the second detector, and
a first intensity of the detection target light in the first state is lower than a second intensity of the detection target light in the second state.

### Technical Proposal 10

The photodetector according to any one of Technical proposals 1-9, wherein
the detection layer includes a quantum cascade active layer.

### Technical Proposal 11

The photodetector according to any one of Technical proposals 1-10, wherein
a subband transition of a carrier occurs in the detection layer.

### Technical Proposal 12

The photodetector according to Technical proposal 7 or 8, wherein
each of the first detector and the second detector further includes a base,
at least a part of the base is between the first electrode and the second electrode,
at least a part of the detection layer is between the base and the second electrode, and
at least a part of the photonic crystal layer is between the detection layer and the second electrode.

### Technical Proposal 13

A photodetector, comprising:
a first electrode;
a second electrode; and
a stacked member, at least a part of the stacked member being between the first electrode and the second electrode; the stacked member including a detection layer and a photonic crystal layer,
the detection layer including:
   a plurality of first semiconductor films; and
   a second semiconductor film provided between the plurality of first semiconductor films,
the photonic crystal layer being configured to supply the detection layer with a detection target light being incident on the photonic crystal layer,
an electrical signal generated between the first electrode and the second electrode is configured to change according to a detection target light being incident on the photonic crystal layer, and
a first number of the plurality of first semiconductor films is not less than 2 and not more than 10.

### Technical Proposal 14

The photodetector according to Technical proposal 13, wherein
the first semiconductor films include In_{z1}Ga_{1-z1}As (0<z1<1), and
the second semiconductor film includes In_{z2}Al_{1-z2}As (0<z2<1).

### Technical Proposal 15

A photodetection system comprising:
a first light-emitter configured to emit a first light; and
a first detector configured to detect a detection target light based on the first light,
each of the first light-emitter and the first detector including a stacked member including a stacked body,
the stacked body including:
   a plurality of first semiconductor films; and
   a second semiconductor film provided between the plurality of first semiconductor films,
a first number of the plurality of first semiconductor films included in the stacked body of the first detector being smaller than a second number of the plurality of first semiconductor films included in the stacked body of the first light-emitter.

### Technical Proposal 16

The photodetection system according to Technical proposal 15, wherein
the plurality of first semiconductor films included in the first detector include In_{z1}Ga_{1-z1}As (0<z1<1), and
the second semiconductor film included in the first detector includes In_{z2}Al_{1-z2}As (0<z2<1).

### Technical Proposal 17

The photodetection system according to Technical proposal 16, wherein
the plurality of first semiconductor films included in the first light-emitting portion include In_{z3}Ga_{1-z3}As (0<z3<1), and
the second semiconductor film included in the first light-emitting portion includes In_{z4}Al_{1-z4}As (0<z4<1).

### Technical Proposal 18

The photodetection system according to Technical proposal 17, wherein
the z1, the z2, the z3, and the z4 satisfy one of a first condition, a second condition, a third condition, and a fourth condition,
in the first condition, the z1 is the same as the z3, and the z2 is the same as the z4,
in the second condition, the z1 is the same as the z3, and the z2 is different from the z4,
in the third condition, the z1 is different from the z3, and the z2 is the same as the z4, and in the fourth condition, the z1 is different from the z3, and the z2 is different from the z4.

### Technical Proposal 19

The photodetection system according to any one of Technical proposals 15-18, wherein
the first number is not less than 2 and not more than 10, and
the second number is more than 10 and not more than 100.

### Technical Proposal 20

The photodetection system according to any one of Technical proposals 15-19, wherein
the stacked member further includes a photonic crystal layer,
the photonic crystal layer included in the first light-emitter overlaps the stacked body included in the first light-emitter, and
the photonic crystal layer included in the first detector overlaps the stacked body included in the first detector.

### Technical Proposal 21

The photodetection system according to Technical proposal 20, wherein
the first detector further includes a first electrode and a second electrode,
at least a part of the stacked member included in the first detector is provided between the first electrode and the second electrode,
the first light-emitter further includes a third electrode and a fourth electrode, and
at least a part of the stacked member included in the first light-emitter is provided between the third electrode and the fourth electrode.

### Technical Proposal 22

The photodetection system according to Technical proposal 21, wherein
an electrical signal generated between the first electrode and the second electrode is configured to change according to the detection target light incident on the photonic crystal layer of the first detector.

### Technical Proposal 23

The photodetection system according to any one of Technical proposals 15-22, wherein
the stacked body includes a quantum cascade active layer.

### Technical Proposal 24

The photodetection system according to any one of technical proposals 15-23, wherein
a subband transition of carriers occurs in the stacked body.

### Technical Proposal 25

A photodetector, comprising:
a first detector,
the first detector including a stacked member including a detection layer 10,
the detection layer including:
   a plurality of first semiconductor films, and
   a second semiconductor film provided between the plurality of first semiconductor films,
the stacked member further including a photonic crystal layer,
the photonic crystal layer being configured to a supply detection target light being incident on the photonic crystal layer to the detection layer,
the first detector further including a first electrode and a second electrode,
at least a part of the stacked member being provided between the first electrode and the second electrode,
an electrical signal generated between the first electrode and the second electrode is configured to change in response to detection target light being incident on the photonic crystal layer, and
the detection layer including a quantum cascade active layer.

According to the embodiment, a photodetector and a photodetection system that can achieve high sensitivity are provided.

In the specification, “vertical” and “parallel” do not only mean strictly vertical and strictly parallel, but also include, for example, variations in the manufacturing process, and may mean substantially vertical and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the photodetectors such as electrode, stacked members, detection layers, photonic crystals, semiconductor films, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all photodetectors practicable by an appropriate design modification by one skilled in the art based on the photodetectors described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A photodetector, comprising:
a first detector; and
a second detector,
each of the first detector and the second detector including a stacked member including a detection layer;
the detection layer including:
a plurality of first semiconductor films, and
a second semiconductor film provided between the plurality of first semiconductor films;
a first number of the plurality of first semiconductor films included in the detection layer of the first detector being smaller than a second number of the plurality of first semiconductor films included in the detection layer of the second detector.

2. The photodetector according to claim 1, wherein
the plurality of first semiconductor films included in the first detector include In_{z1}Ga_{1-z1}As (0<z1<1), and
the second semiconductor film included in the first detector includes In_{z2}Al_{1-z2}As (0<z2<1).

3. The photodetector according to claim 2, wherein
the plurality of first semiconductor films included in the second detector include In_{z3}Ga_{1-z3}As (0<z3<1), and
the second semiconductor film included in the second detector includes In_{z4}Al_{1-z4}As (0<z4<1).

4. The photodetector according to claim 3, wherein
the z1, the z2, the z3, and z4 satisfy one of a first condition, the second condition, the third condition, and the fourth condition,
in the first condition, the z1 is the same as the z3, and the z2 is the same as the z4,
in the second condition, the z1 is the same as the z3, and the z2 is different from the z4,
in the third condition, the z1 is different from the z3, and the z2 is the same as the z4, and
in the fourth condition, the z1 is different from the z3, and the z2 is different from the z4.

5. The photodetector according to claim 1, wherein
the first number is not less than 2 and not more than 10, and
the second number is more than 10 and not more than 100.

6. The photodetector according to claim 1, wherein
the stacked member further includes a photonic crystal layer, and
the photonic crystal layer is configured to supply the detection layer with a detection target light being incident on the photonic crystal layer.

7. The photodetector according to claim 6, wherein
the first detector and the second detector each further include a first electrode and a second electrode, and
at least a part of the stacked member is provided between the first electrode and the second electrode.

8. The photodetector according to claim 7, wherein
an electrical signal generated between the first electrode and the second electrode is configured to change according to the detection target light that is incident on the photonic crystal layer.

9. The photodetector according to claim 6, further comprising:
a controller,
the controller being configured to output a detection signal corresponding to the detection target light,
in a first state, the detection signal is based on a first signal obtained from the first detector,
in a second state, the detection signal is based on a second signal obtained from the second detector, and
a first intensity of the detection target light in the first state is lower than a second intensity of the detection target light in the second state.

10. The photodetector according to claim 1, wherein
the detection layer includes a quantum cascade active layer.

11. The photodetector according to claim 1, wherein
a subband transition of a carrier occurs in the detection layer.

12. The photodetector according to claim 7, wherein
each of the first detector and the second detector further includes a base,
at least a part of the base is between the first electrode and the second electrode,
at least a part of the detection layer is between the base and the second electrode, and
at least a part of the photonic crystal layer is between the detection layer and the second electrode.

13. A photodetector, comprising:
a first electrode;
a second electrode; and
a stacked member, at least a part of the stacked member being between the first electrode and the second electrode; the stacked member including a detection layer and a photonic crystal layer,
the detection layer including:
a plurality of first semiconductor films; and
a second semiconductor film provided between the plurality of first semiconductor films,
the photonic crystal layer being configured to supply the detection layer with a detection target light being incident on the photonic crystal layer,
an electrical signal generated between the first electrode and the second electrode is configured to change according to a detection target light being incident on the photonic crystal layer, and
a first number of the plurality of first semiconductor films is not less than 2 and not more than 10.

14. The photodetector according to claim 13, wherein
the first semiconductor films include In_{z1}Ga_{1-z1}As (0<z1<1), and
the second semiconductor film includes In_{z2}Al_{1-z2}As (0<z2<1).

15. A photodetection system comprising:
a first light-emitter configured to emit a first light; and
a first detector configured to detect a detection target light based on the first light,
each of the first light-emitter and the first detector including a stacked member including a stacked body,
the stacked body including:
a plurality of first semiconductor films; and
a second semiconductor film provided between the plurality of first semiconductor films,
a first number of the plurality of first semiconductor films included in the stacked body of the first detector being smaller than a second number of the plurality of first semiconductor films included in the stacked body of the first light-emitter.

16. The photodetection system according to claim 15, wherein
the plurality of first semiconductor films included in the first detector include In_{z1}Ga_{1-z1}As (0<z1<1), and
the second semiconductor film included in the first detector includes In_{z2}Al_{1-z2}As (0<z2<1).

17. The photodetection system according to claim 16, wherein
the plurality of first semiconductor films included in the first light-emitting portion include In_{z3}Ga_{1-z3}As (0<z3<1), and
the second semiconductor film included in the first light-emitting portion includes In_{z4}Al_{1-z4}As (0<z4<1).

18. The photodetection system according to claim 17, wherein
the z1, the z2, the z3, and the z4 satisfy one of a first condition, a second condition, a third condition, and a fourth condition,
in the first condition, the z1 is the same as the z3, and the z2 is the same as the z4,
in the second condition, the z1 is the same as the z3, and the z2 is different from the z4,
in the third condition, the z1 is different from the z3, and the z2 is the same as the z4, and
in the fourth condition, the z1 is different from the z3, and the z2 is different from the z4.

19. The photodetection system according to claim 15, wherein
the first number is not less than 2 and not more than 10, and
the second number is more than 10 and not more than 100.

20. A photodetector, comprising:
a first detector,
the first detector including a stacked member including a detection layer 10,
the detection layer including:
a plurality of first semiconductor films, and
a second semiconductor film provided between the plurality of first semiconductor films,
the stacked member further including a photonic crystal layer,
the photonic crystal layer being configured to a supply detection target light being incident on the photonic crystal layer to the detection layer,
the first detector further including a first electrode and a second electrode,
at least a part of the stacked member being provided between the first electrode and the second electrode,
an electrical signal generated between the first electrode and the second electrode is configured to change in response to detection target light being incident on the photonic crystal layer, and
the detection layer including a quantum cascade active layer.
